(19) United States
(12) Patent Application Publication
(10) Pub. No.: US 2010/0213476 A1
(43) Pub. Date: Aug. 26, 2010

(54) GROUP-III NITRIDE COMPOUND SEMICONDUCTOR LIGHT-EMITTING DEVICE, METHOD OF MANUFACTURING GROUP-III NITRIDE COMPOUND SEMICONDUCTOR LIGHT-EMITTING DEVICE, AND LAMP

(75) Inventors: Yasunori Yokoyama, Ichihara-shi (JP); Hiromitsu Sakai, Chiba-shi (JP); Hisayuki Miki, Chiba-shi (JP)

Correspondence Address: SUGHRUE MION, PLLC, 2100 PENNSYLVANIA AVENUE, N.W., SUITE 800, WASHINGTON, DC, 20037, US

(73) Assignee: Showa Denko K.K., Minato-ku (JP)

(21) Appl. No.: 12/377,273

(22) PCT Filed: Sep. 26, 2007
(86) PCT No.: PCT/JP2007/068690

§ 371 Date: Feb. 12, 2009

(30) Foreign Application Priority Data
Sep. 26, 2006 (JP) 2006-260878
Jul. 30, 2007 (JP) 2007-197473

(51) Int. Cl. H01L 33/30; H01L 21/20

(52) U.S. Cl. 257/94; 438/46; 257/E33.028; 257/E33.025; 257/E21.09

(57) ABSTRACT

The present invention provides a group-III nitride compound semiconductor light-emitting device having high productivity and good emission characteristics, a method of manufacturing a group-III nitride compound semiconductor light-emitting device, and a lamp. The method of manufacturing a group-III nitride compound semiconductor light-emitting device includes: a pre-process of performing plasma processing on a substrate (11); a sputtering process of forming an intermediate layer (12) made of at least a group-III nitride compound on the substrate (11) using a sputtering method after the pre-process; and a process of sequentially forming an n-type semiconductor layer (14) including an underlying layer (14a), a light-emitting layer (15), and a p-type semiconductor layer (16) on the intermediate layer (12).

### TECHNICAL FIELD

The present invention relates to a group-III nitride compound semiconductor light-emitting device applicable to, for example, a light-emitting diode (LED), a laser diode (LD), or an electronic device, a method of manufacturing a group-III nitride compound semiconductor light-emitting device, and a lamp.

Priority is claimed on Japanese Patent Application No. 2006-260878, filed Sep. 26, 2006, and Japanese Patent Application No. 2007-197473, filed Jul. 30, 2007, the content of which is incorporated herein by reference.

### BACKGROUND ART

A group-III nitride semiconductor light-emitting device has a direct-transition-type energy band gap corresponding to the range from visible light to ultraviolet light, and has high emission efficiency. Therefore, the group-III nitride semiconductor light-emitting device has been used as a light-emitting device, such as an LED or an LD.

When the group-III nitride semiconductor light-emitting device is used for an electronic device, it is possible to obtain an electronic device having better characteristics, as compared to when a group-III-V compound semiconductor according to the related art is used.

In general, a single crystal wafer made of a group-III-V compound semiconductor is obtained by growing a crystal on a single crystal wafer made of a different material. There is a large lattice mismatch between the substrate and a group-III nitride semiconductor crystal epitaxially grown on the substrate. For example, when a gallium nitride (GaN) is grown on a sapphire (Al₂O₃) substrate, there is 16% of lattice mismatch therebetween. When a gallium nitride is grown on a SiC substrate, there is 6% of lattice mismatch therebetween.

In general, the large lattice mismatch makes it difficult to epitaxially grow a crystal on the substrate directly. Even though the crystal is grown on the substrate, it is difficult to obtain a crystal having high crystallinity.

Therefore, a method has been proposed in which, when a group-III nitride semiconductor crystal is epitaxially grown on a sapphire single crystal substrate or a SiC single crystal substrate by a metal organic chemical vapor deposition (MOCVD) method, a so-called low temperature buffer layer made of aluminum nitride (AlN) or aluminum gallium nitride (AlGaN) is formed on the substrate and a group-III nitride semiconductor crystal is epitaxially grown on the buffer layer at a high temperature (for example, see Patent Documents 1 and 2). This method has generally been used.

However, in the methods disclosed in Patent Documents 1 and 2, basically, since there is a lattice mismatch between the substrate and the group-III nitride semiconductor crystal formed on the substrate, a so-called threading dislocation extending to the surface of a crystal is formed inside the crystal, which results in the distortion of the crystal.

Therefore, it is necessary to appropriately change the structure in order to obtain sufficient emission power and high productivity.

Further, a technique for forming the buffer layer using deposition methods other than the MOCVD method has been proposed.

For example, a method has been proposed which forms a buffer layer using an RF sputtering method and grows on the buffer layer a crystal having the same composition as the buffer layer using an MOCVD method (for example, Patent Document 3). However, in the method disclosed in Patent Document 3, it is difficult to obtain a stable and good crystal.

Therefore, in order to obtain a stable and good crystal, for example, the following methods have been proposed: a method of forming a buffer layer and performing annealing in a mixed gas atmosphere of ammonia and hydrogen (for example, Patent Document 4); and a method of forming a buffer layer at a temperature of more than 400° C. using DC sputtering (for example, Patent Document 5). In the methods disclosed in Patent Documents 4 and 5, a substrate is formed of sapphire, silicon, silicon carbide, zinc oxide, gallium phosphide, gallium arsenide, magnesium oxide, manganese oxide, or a group-III nitride compound semiconductor single crystal. Among these materials, an a-plane sapphire substrate is preferable.

In addition, a method has been proposed which performs reverse sputtering on a semiconductor layer using an Ar gas as a pre-process before electrodes are formed on the semiconductor layer (for example, Patent Document 6). In the method disclosed in Patent Document 6, reverse sputtering is performed on the surface of a group-III nitride compound semiconductor layer to improve electric contact characteristics between the semiconductor layer and the electrodes.

However, even though the method disclosed in Patent Document 6 is applied to the pre-process of the substrate, a lattice mismatch occurs between the substrate and the semiconductor layer. As a result, it is difficult to form a semiconductor layer having high crystallinity on the substrate.

[Patent Document 1] Japanese Patent No. 3026087

[Patent Document 2] JP-A-4-297023

[Patent Document 3] JP-B-5-86646

[Patent Document 4] Japanese Patent No. 3440873

[Patent Document 5] Japanese Patent No. 3700492

[Patent Document 6] JP-A-8-264478

### DISCLOSURE OF THE INVENTION

### Problems to be Solved by the Invention

As described above, in the above-mentioned methods according to the related art, after the buffer layer is formed on the substrate without any pre-process, a group-III nitride compound semiconductor is epitaxially grown on the buffer layer. Therefore, there is a lattice mismatch between the substrate and the group-III nitride semiconductor crystal, and it is difficult to obtain a stable and good crystal.

The present invention has been made in order to solve the above problems, and an object of the present invention is to provide a group-III nitride compound semiconductor light-emitting device having high productivity and good emission characteristics, a method of manufacturing a group-III nitride compound semiconductor light-emitting device by forming a buffer layer on a substrate by a method capable of forming a uniform crystal film in a short time and growing a group-III nitride semiconductor on the buffer layer, and a lamp.

### Means for Solving the Problems

The inventors have conducted studies in order to solve the above problems and found that it is possible to obtain a stable and good group-III nitride semiconductor crystal by appropriately performing a pre-process on a substrate before a buffer layer is formed by a sputtering method and exposing the surface of the substrate such that a lattice match is obtained between the substrate and a group-III nitride compound, by which the present invention was achieved.

That is, the present invention is as follows.

According to a first aspect of the present invention, a method of manufacturing a group-III nitride compound semiconductor light-emitting device includes: a pre-process of performing plasma processing on a substrate; a sputtering process of forming an intermediate layer made of at least a group-III nitride compound on the substrate using a sputtering method after the pre-process; and a process of sequentially forming an n-type semiconductor layer including an underlying layer, a light-emitting layer, and a p-type semiconductor layer on the intermediate layer.

According to a second aspect of the present invention, in the method of manufacturing a group-III nitride compound semiconductor light-emitting device according to the first aspect, preferably, in the pre-process, gas including nitrogen is introduced into a chamber.

According to a third aspect of the present invention, in the method of manufacturing a group-III nitride compound semiconductor light-emitting device according to the second aspect, preferably, in the pre-process, the partial pressure of the gas including nitrogen introduced into the chamber is in the range of 1×10⁻² Pa to 10 Pa.

According to a fourth aspect of the present invention, in the method of manufacturing a group-III nitride compound semiconductor light-emitting device according to any one of the first to third aspects, preferably, in the pre-process, the internal pressure of the chamber is in the range of 0.1 to 5 Pa.

According to a fifth aspect of the present invention, in the method of manufacturing a group-III nitride compound semiconductor light-emitting device according to any one of the first to fourth aspects, preferably, the process time of the pre-process is in the range of 30 seconds to 3600 seconds.

According to a sixth aspect of the present invention, in the method of manufacturing a group-III nitride compound semiconductor light-emitting device according to the fifth aspect, preferably, the process time of the pre-process is in the range of 60 seconds to 600 seconds.

According to a seventh aspect of the present invention, in the method of manufacturing a group-III nitride compound semiconductor light-emitting device according to any one of the first to sixth aspects, preferably, in the pre-process, the temperature of the substrate is in the range of 25° C. to 1000° C.

According to an eighth aspect of the present invention, in the method of manufacturing a group-III nitride compound semiconductor light-emitting device according to the seventh aspect, preferably, in the pre-process, the temperature of the substrate is in the range of 300° C. to 800° C.

According to a ninth aspect of the present invention, in the method of manufacturing a group-III nitride compound semiconductor light-emitting device according to any one of the first to eighth aspects, preferably, the pre-process and the sputtering process are performed in the same chamber.

According to a tenth aspect of the present invention, in the method of manufacturing a group-III nitride compound semiconductor light-emitting device according to any one of the first to ninth aspects, preferably, the plasma processing performed in the pre-process is reverse sputtering.

According to an eleventh aspect of the present invention, in the method of manufacturing a group-III nitride compound semiconductor light-emitting device according to any one of the first to tenth aspects, preferably, in the pre-process, an RF power supply is used to generate plasma, thereby performing the reverse sputtering.

According to a twelfth aspect of the present invention, in the method of manufacturing a group-III nitride compound semiconductor light-emitting device according to the eleventh aspect, preferably, in the pre-process, the reverse sputtering is performed by generating nitrogen plasma using the RF power supply.

According to a thirteenth aspect of the present invention, in the method of manufacturing a group-III nitride compound semiconductor light-emitting device according to any one of the first to twelfth aspects, preferably, the intermediate layer is formed so as to cover 90% or more of the surface of the substrate.

According to a fourteenth aspect of the present invention, in the method of manufacturing a group-III nitride compound semiconductor light-emitting device according to any one of the first to thirteenth aspects, preferably, the sputtering process uses a raw material including a group-V element.

According to a fifteenth aspect of the present invention, in the method of manufacturing a group-III nitride compound semiconductor light-emitting device according to any one of the first to fourteenth aspects, preferably, in the sputtering process, the intermediate layer is formed by a reactive sputtering method that introduces the raw material including the group-V element into a reactor.

According to a sixteenth aspect of the present invention, in the method of manufacturing a group-III nitride compound semiconductor light-emitting device according to the fourteenth or fifteenth aspect, preferably, the group-V element is nitrogen.

According to a seventeenth aspect of the present invention, in the method of manufacturing a group-III nitride compound semiconductor light-emitting device according to the fourteenth or fifteenth aspect, preferably, ammonia is used as the raw material including the group-V element.

According to an eighteenth aspect of the present invention, in the method of manufacturing a group-III nitride compound semiconductor light-emitting device according to any one of the first to seventeenth aspects, preferably, in the sputtering process, the intermediate layer is formed by an RF sputtering method.

According to a nineteenth aspect of the present invention, in the method of manufacturing a group-III nitride compound semiconductor light-emitting device according to the eighteenth aspect, preferably, in the sputtering process, the intermediate layer is formed by the RF sputtering method while moving a magnet of a cathode.

According to a twentieth aspect of the present invention, in the method of manufacturing a group-III nitride compound semiconductor light-emitting device according to any one of the first to nineteenth aspects, preferably, in the sputtering process, when the intermediate layer is formed, the temperature of the substrate is in the range of 400° C. to 800° C.

According to a twenty-first aspect of the present invention, in the method of manufacturing a group-III nitride compound semiconductor light-emitting device according to any one of the first to twentieth aspects, preferably, the underlying layer is formed on the intermediate layer by an MOCVD method.

According to a twenty-second aspect of the present invention, in the method of manufacturing a group-III nitride compound semiconductor light-emitting device according to any one of the first to twentieth aspects, preferably, the underlying layer is formed on the intermediate layer by a reactive sputtering method.

According to a twenty-third aspect of the present invention, in the method of manufacturing a group-III nitride compound semiconductor light-emitting device according to any one of the first to twenty-second aspects, preferably, when the underlying layer is formed, the temperature of the substrate is higher than 900° C.

According to a twenty-fourth aspect of the present invention, a group-III nitride compound semiconductor light-emitting device includes: a substrate that is pre-processed by plasma processing; an intermediate layer that is made of at least a group-III nitride compound and is formed on the substrate by a sputtering method; an n-type semiconductor layer including an underlying layer; a light-emitting layer; and a p-type semiconductor layer. The n-type semiconductor layer, the light-emitting layer, and the p-type semiconductor layer are sequentially formed on the intermediate layer.

According to a twenty-fifth aspect of the present invention, in the group-III nitride compound semiconductor light-emitting device according to the twenty-fourth aspect, preferably, the intermediate layer is formed of a single crystal.

According to a twenty-sixth aspect of the present invention, in the group-III nitride compound semiconductor light-emitting device according to the twenty-fourth aspect, preferably, the intermediate layer is formed of a columnar crystal.

According to a twenty-seventh aspect of the present invention, in the group-III nitride compound semiconductor light-emitting device according to the twenty-sixth aspect, preferably, in the intermediate layer, the average of the widths of grains of the columnar crystals is in the range of 1 to 100 nm.

According to a twenty-eighth aspect of the present invention, in the group-III nitride compound semiconductor light-emitting device according to the twenty-sixth aspect, preferably, in the intermediate layer, the average of the widths of grains of the columnar crystals is in the range of 1 to 70 nm.

According to a twenty-ninth aspect of the present invention, in the group-III nitride compound semiconductor light-emitting device according to any one of the twenty-fourth to twenty-eighth aspects, preferably, the intermediate layer is formed so as to cover 90% or more of the front surface of the substrate.

According to a thirtieth aspect of the present invention, in the group-III nitride compound semiconductor light-emitting device according to any one of the twenty-fourth to twenty-ninth aspects, preferably, the thickness of the intermediate layer is in the range of 10 to 500 nm.

According to a thirty-first aspect of the present invention, in the group-III nitride compound semiconductor light-emitting device according to any one of the twenty-fourth to twenty-ninth aspects, preferably, the thickness of the intermediate layer is in the range of 20 to 100 nm.

According to a thirty-second aspect of the present invention, in the group-III nitride compound semiconductor light-emitting device according to any one of the twenty-fourth to thirty-first aspects, preferably, the intermediate layer has a composition including Al.

According to a thirty-third aspect of the present invention, in the group-III nitride compound semiconductor light-emitting device according to the thirty-second aspect, preferably, the intermediate layer is formed of AlN.

According to a thirty-fourth aspect of the present invention, in the group-III nitride compound semiconductor light-emitting device according to any one of the twenty-fourth to thirty-third aspects, preferably, the underlying layer is formed of a GaN-based compound semiconductor.

According to a thirty-fifth aspect of the present invention, in the group-III nitride compound semiconductor light-emitting device according to the thirty-fourth aspect, preferably, the underlying layer is formed of AlGaN.

According to a thirty-sixth aspect of the present invention, a group-III nitride compound semiconductor light-emitting device is manufactured by the manufacturing method according to any one of the first to twenty-third aspects.

According to a thirty-seventh aspect of the present invention, a lamp includes the group-III nitride compound semiconductor light-emitting device according to any one of the twenty-fourth to thirty-sixth aspects.

### ADVANTAGES OF THE INVENTION

The present invention provides a group-III nitride compound semiconductor light-emitting device and a method of manufacturing a group-III nitride compound semiconductor light-emitting device. The method of manufacturing a group-III nitride compound semiconductor light-emitting device includes: a pre-process of performing plasma processing on a substrate; and a sputtering process of forming an intermediate layer on the substrate using a sputtering method after the pre-process. According to this structure, the intermediate layer having a uniform crystal structure is formed on the surface of the substrate, and there is no lattice mismatch between the substrate and a semiconductor layer made of a group-III nitride semiconductor.

Therefore, it is possible to effectively grow a group-III nitride semiconductor having high crystallinity on the substrate. As a result, it is possible to obtain a group-III nitride compound semiconductor light-emitting device having high productivity and good emission characteristics.

### BRIEF DESCRIPTION OF THE DRAWINGS

FIG. 1 is a cross-sectional view schematically illustrating an example of the structure of a laminated semiconductor of a group-III nitride compound semiconductor light-emitting device according to the present invention.

FIG. 2 is a plan view schematically illustrating an example of the structure of the group-III nitride compound semiconductor light-emitting device according to the present invention.

FIG. 3 is a cross-sectional view schematically illustrating an example of the structure of the group-III nitride compound semiconductor light-emitting device according to the present invention.

FIG. 4 is a diagram schematically illustrating a lamp including the group-III nitride compound semiconductor light-emitting device according to the present invention.

FIG. 5 is a diagram illustrating an example of the group-III nitride compound semiconductor light-emitting device according to the present invention, and is a graph illustrating data of the X-ray half width of a GaN crystal.

FIG. 6 is a diagram illustrating an example of the group-III nitride compound semiconductor light-emitting device according to the present invention, and is a graph illustrating data of the X-ray half width of a GaN crystal.

FIGS. 7A to 7C are diagram schematically illustrating an example of the group-III nitride compound semiconductor light-emitting device according to the present invention, and shows the structure of an intermediate layer formed on a substrate.

FIG. 8 is a diagram schematically illustrating an example of a method of manufacturing the group-III nitride compound semiconductor light-emitting device according to the present invention, and shows the schematic structure of a sputtering apparatus.

### BEST MODE FOR CARRYING OUT THE INVENTION

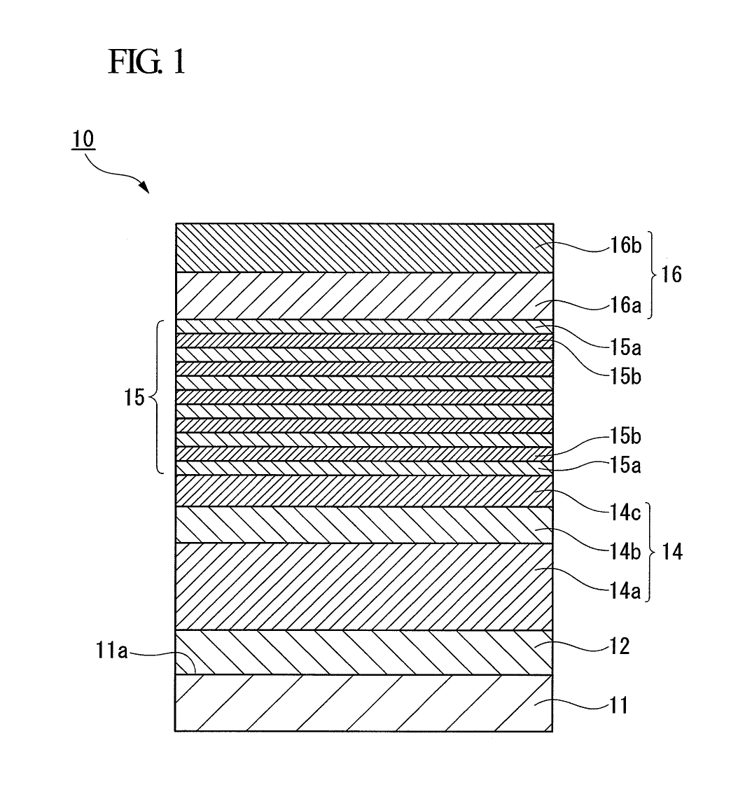

Hereinafter, a group-III nitride compound semiconductor light-emitting device, a method of manufacturing a group-III nitride compound semiconductor light-emitting device, and a lamp according to an embodiment of the present invention will be described with reference to FIGS. 1 to 6.

In a method of manufacturing a group-III nitride compound semiconductor light-emitting device according to this embodiment, an intermediate layer 12 made of at least a group-III nitride compound is formed on a substrate 11, and an n-type semiconductor layer 14 having an underlying layer 14a, a light-emitting layer 15, and a p-type semiconductor layer 16 are sequentially formed on the intermediate layer 12. The manufacturing method includes a pre-process that performs plasma processing on the substrate 11 and a sputtering process that forms the intermediate layer 12 on the substrate 11 using a sputtering method after the pre-process.

In the manufacturing method according to this embodiment, when a group-III nitride compound semiconductor crystal is epitaxially grown on the substrate 11, the pre-process for performing plasma processing on the substrate 11 is executed before the sputtering process for forming the intermediate layer 12 made of a group-III nitride compound on the substrate 11. The plasma processing performed on the substrate 11 makes it possible to effectively grow a group-III nitride semiconductor having high crystallinity.

A group-III nitride compound semiconductor light-emitting device (hereinafter, simply referred to as a light-emitting device) manufactured by the manufacturing method according to this embodiment has a semiconductor laminated structure shown in FIG. 1. In a laminated semiconductor 10, the intermediate layer 12 that is made of at least a group-III nitride compound is formed on the substrate 11, and the n-type semiconductor layer 14 having the underlying layer 14a, the light-emitting layer 15, and the p-type semiconductor layer 16 are sequentially formed on the intermediate layer 12. In addition, the underlying layer 14a is formed on the intermediate layer 12, and the substrate 11 is pre-processed by plasma processing. The intermediate layer 12 is formed by a sputtering method.

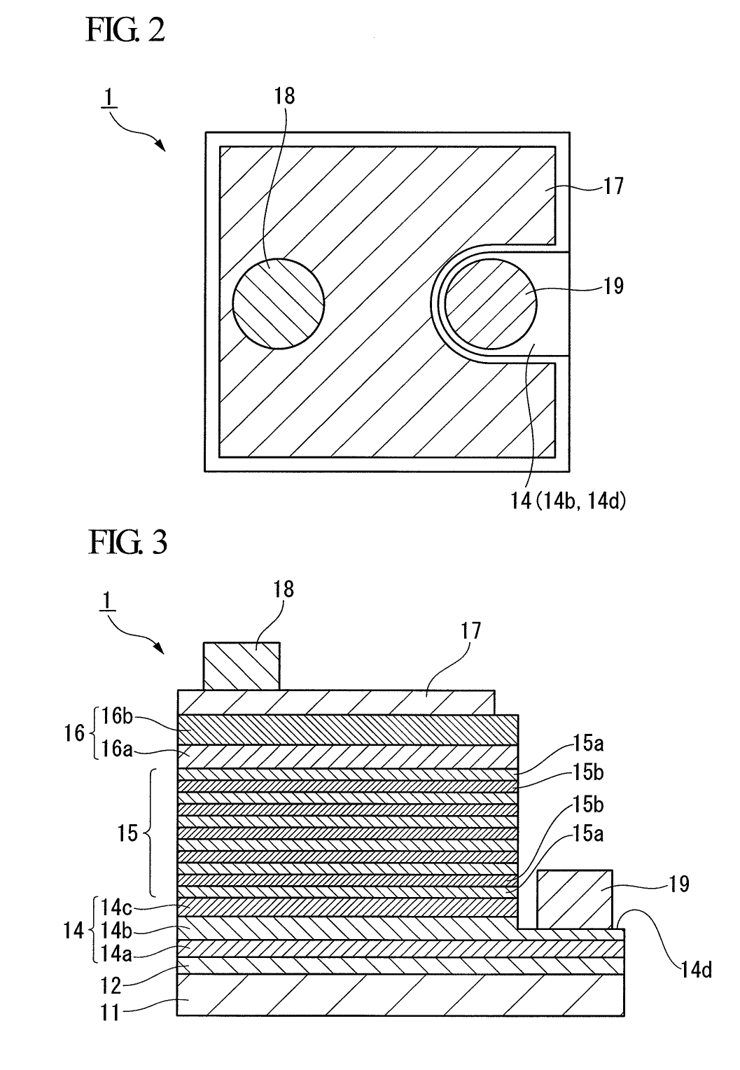

As shown in FIGS. 2 and 3, in the laminated semiconductor 10 according to this embodiment, a transparent positive electrode 17 is formed on the p-type semiconductor layer 16, and a positive electrode bonding pad 18 is formed on the transparent positive electrode. In addition, an exposed region 14d is formed in an n-type contact layer 14b of the n-type semiconductor layer 14, and a negative electrode 19 is formed on the exposed region 14d. In this way, a light-emitting device 1 is formed.

Next, the pre-process and the sputtering process included in the method of manufacturing a group-III nitride compound semiconductor light-emitting device according to this embodiment will be described in detail.

### [Pre-Process]

It is preferable that the plasma processing executed in the pre-process according to this embodiment be performed in plasma including gas that generates an active plasma species, such as nitrogen or oxygen. In particular, a nitrogen gas is preferable.

In addition, it is preferable that the plasma processing in the pre-process according to this embodiment be reverse sputtering.

In the pre-process according to this embodiment, a voltage is applied between the substrate 11 and a chamber such that plasma particles effectively act on the substrate 11.

As a raw material gas for performing plasma processing on the substrate 11, a gas including only one kind of component or a mixture of gases including several kinds of components may be used. For example, the partial pressure of the raw material gas, such as nitrogen, is preferably in the range of 1×10⁻² to 10 Pa, more preferably, 0.1 to 5 Pa. When the partial pressure of the raw material gas is excessively high, the energy of the plasma particles is reduced, and the pre-process effect of the substrate 11 is lowered. On the other hand, when the partial pressure is excessively low, the energy of the plasma particles is excessively high, and the substrate 11 is likely to be damaged.

It is preferable that the pre-process using plasma processing be performed for 30 seconds to 3600 seconds (1 hour). If the process time is shorter than the above range, it is difficult to obtain the effect of the plasma processing. If the process time is longer than the above range, characteristics are not considerably improved, but the rate of operation is likely to be lowered. It is more preferable that the pre-process using plasma processing be performed for 60 seconds to 600 seconds (10 minutes).

The temperature of the plasma processing is preferably in the range of 25 to 1000° C. If the process temperature is excessively low, it is difficult to obtain a sufficient effect of the plasma processing. On the other hand, if the process temperature is excessively high, the surface of the substrate is likely to be damaged. It is more preferable that the temperature of the plasma processing be in the range of 300° C. to 800° C.

In the pre-process according to this embodiment, a chamber that is same as or different from that used to form an intermediate layer in the sputtering process, which will be described below, may be used to perform the plasma processing. When a common chamber is used for the pre-process and the sputtering process, it is possible to reduce manufacturing costs. When reverse sputtering is used as the plasma processing under the conditions used for the deposition of the intermediate layer, it is possible to reduce the time required to change the sputtering conditions, and the rate of operation is improved.

In the pre-process according to this embodiment, it is preferable to generate plasma used for the plasma processing using an RF discharge. When plasma is generated by the RF discharge, it is also possible to perform the pre-process using the plasma processing on a substrate made of an insulating material.

The pre-process performed on the substrate 11 may also adopt a wet method. For example, a known RCA cleaning method is performed on a substrate made of silicon to hydrogen-terminate the surface of the substrate. In this way, a process for forming an intermediate layer on the substrate is stabilized in the sputtering process, which will be described in detail.

In this embodiment, after plasma processing is performed on the substrate 11 in the pre-process, the intermediate layer 12 made of a group-III nitride compound is formed on the substrate in a sputtering process, which will be described below, and the n-type semiconductor layer 14 including the underlying layer 14a is formed on the intermediate layer 12. In this way, the crystallinity of a group-III nitride semiconductor is significantly improved, and the emission characteristics of a light-emitting device are improved, which can be seen from the following Examples.

As a mechanism for performing plasma processing on the substrate 11 to obtain the above-mentioned effects, the following is used: a mechanism of removing a contaminant adhered to the surface of the substrate 11 using reverse sputtering to expose the surface of the substrate 11 such that a crystal lattice match between the surface of the substrate and a group-III nitride compound is achieved.

In the pre-process according to this embodiment, plasma processing is performed on the surface of the substrate 11 in a mixed atmosphere of ion components and radical components having no charge.

For example, when only the ion components are supplied to the surface of the substrate to remove a contaminant from the surface of the substrate, excessively high energy is supplied to damage the surface of the substrate, and the quality of a crystal grown on the substrate deteriorates.

In the pre-process according to this embodiment, as described above, plasma processing is performed in a mixed atmosphere of ion components and radical components to react a reactive species having appropriate energy with the substrate 11. Therefore, it is possible to remove, for example, a contaminant from the surface of the substrate 11 without damaging the surface of the substrate. In order to obtain these effects, any of the following mechanisms may be used: a mechanism that uses plasma including a small amount of ion components to prevent the damage of the surface of the substrate; and a mechanism that processes the surface of a substrate in plasma to remove a contaminant from the surface of the substrate.

### [Sputtering Process]

The sputtering process according to this embodiment uses a sputtering method to form the intermediate layer 12 on the substrate 11. For example, in the sputtering process, the intermediate layer 12 is formed by activating and reacting a metal raw material with gas including a group-V element in plasma.

In the sputtering method, a technique has generally been used which confines plasma in a magnetic field to improve plasma density, thereby improving deposition efficiency. According to this technique, it is possible to make the surface of a sputtering target uniform by changing the position of a magnet. A method of moving the magnet can be appropriately selected depending on the kind of sputtering apparatus. For example, it is possible to swing or rotate the magnet.

As such, it is preferable to use an RF sputtering method that changes the position of a magnet of a cathode to perform deposition since the RF sputtering method can improve deposition efficiency when the intermediate layer 12 is formed on the side surface of the substrate 11, which will be described in detail below.

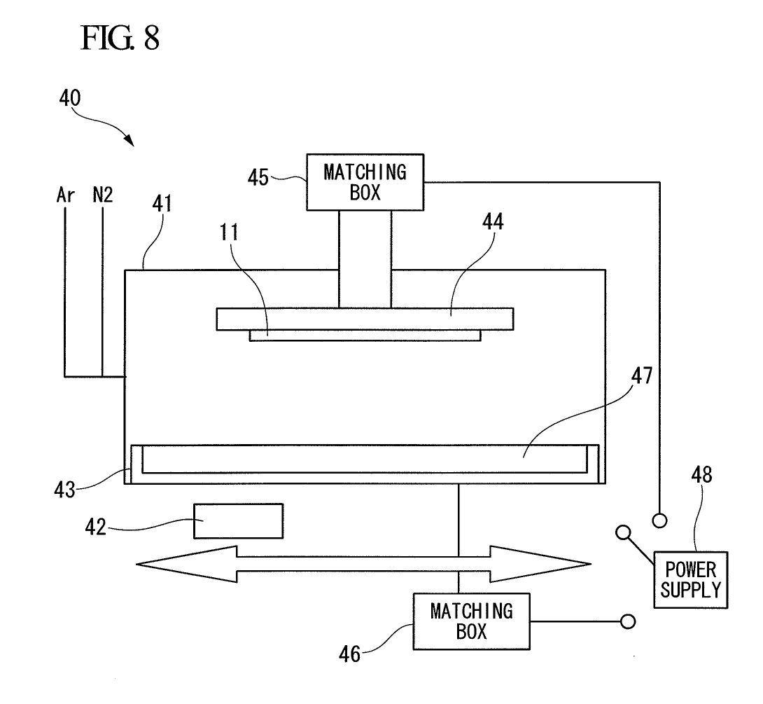

In a sputtering apparatus 40 shown in FIG. 8, a magnet 42 is provided below a metal target 47 (a lower side in FIG. 8), and the magnet 42 is swung below the metal target 47 by a driving device (not shown). A nitrogen gas and an argon gas are supplied into a chamber 41, and an intermediate layer is formed on the substrate 11 attached to a heater 44. In this case, as described above, since the magnet 42 is swung below the metal target 47, plasma confined in the chamber 41 is moved. Therefore, it is possible to form a uniform intermediate layer on the side surface 11b of the substrate 11 as well as the front surface 11a.

When the sputtering method is used to form the intermediate layer 12, important parameters other than the temperature of the substrate 11 include, for example, the partial pressure of nitrogen and the internal pressure of a furnace.

It is preferable that the internal pressure of a furnace when the intermediate layer 12 is formed by the sputtering method be higher than or equal to 0.3 Pa. If the internal pressure of the furnace is lower than 0.3 Pa, the amount of nitrogen is small, and there is a concern that the sputtering metal without being nitrified will be adhered to the substrate 11. The upper limit of the internal pressure of the furnace is not particularly limited, but the furnace needs to have a sufficient internal pressure to generate plasma.

It is preferable that the ratio of the flow rate of nitrogen (N₂) to the flow rate of Ar be in the range of 20% to 80%. If the ratio of the flow rate of nitrogen to the flow rate of Ar is lower than 20%, there is a concern that a sputtering metal without being nitrified will be adhered to the substrate 11. If the ratio of the flow rate of nitrogen to the flow rate of Ar is higher than 80%, the amount of Ar is relatively small, and a sputtering rate is reduced. It is more preferable that that the ratio of the flow rate of nitrogen (N₂) to the flow rate of Ar be in the range of 50% to 80%.

When the intermediate layer 12 is formed, a deposition rate is preferably in the range of 0.01 nm/s to 10 nm/s. If the deposition rate is lower than 0.01 nm/s, a film is not formed, but is scattered in island shapes. As a result, it is difficult to cover the entire front surface of the substrate 11. If the deposition rate is higher than 10 nm/s, a crystal film is not formed, but an amorphous film is formed.

When the intermediate layer 12 is formed by the sputtering method, it is preferable to use a reactive sputtering method that introduces a group-V raw material into a reactor.

In general, in the sputtering method, as the degree of purity of a target material is increased, the quality of a thin film, such as the crystallinity of a thin film, is improved. When the intermediate layer 12 is formed by the sputtering method, a group-III nitride compound semiconductor may be used as a target material, serving as a raw material, and sputtering may be performed in inert gas plasma, such as Ar gas plasma. In the reactive sputtering method, a group-III elemental metal or a mixture thereof used as a target material can have a purity that is higher than that of a group-III nitride compound semiconductor. Therefore, the reactive sputtering method can improve the crystallinity of the intermediate layer 12.

When the intermediate layer 12 is formed, the temperature of the substrate 11 is preferably in the range of 300 to 800° C., more preferably, 400 to 800° C. If the temperature of the substrate 11 is lower than the lower limit, it is difficult for the intermediate layer 12 to cover the entire surface of the substrate 11, and the surface of the substrate 11 is likely to be exposed. If the temperature of the substrate 11 is higher than the upper limit, the migration of a metal raw material is excessively activated, and the intermediate layer may not serve as a buffer layer.

As a method of changing a metal raw material into plasma using sputtering to deposit a mixed crystal as an intermediate layer, any of the following methods may be used: a method of preparing a target made of a mixture of metal materials (an alloy is not necessarily formed) in advance; and a method of preparing two targets made of different materials and sputtering the targets at the same time. For example, when a film having a predetermined composition is formed, a target made of a mixture of materials may be used. When several films having different compositions are formed, a plurality of targets may be provided in the chamber.

A commonly known nitride compound may be used as a nitrogen raw material used in this embodiment, without any restrictions. However, it is preferable that ammonia or nitrogen (N₂) that is relatively inexpensive and easy to treat be used as the raw material.

It is preferable to use ammonia because it has high decomposition efficiency and can be deposited at a high growing speed. However, the ammonia has high reactivity and toxicity. Therefore, the ammonia requires a detoxification facility or a gas detector, and it is necessary that a member used for a reactor be made of a material having high chemical stability.

When nitrogen (N₂) is used as a raw material, a simple apparatus can be used, but it is difficult to obtain a high reaction rate. However, when a method of decomposing nitrogen with, for example, an electric field or heat and introducing it into an apparatus is used, it is possible to obtain a deposition rate that is sufficient for industrial manufacture but is lower than that when ammonia is used. Therefore, nitrogen is most preferable in terms of manufacturing costs.

As described above, it is preferable that the intermediate layer 12 be formed so as to cover the side surface of the substrate 11. In addition, it is most preferable that the intermediate layer 12 be formed so as to cover the side surface and the rear surface of the substrate 11. However, when an intermediate layer is formed by a deposition method according to the related art, it is necessary to perform a maximum of 6 to 8 deposition processes, and it takes a long time to form the intermediate layer. As another deposition method, the following may be used: a method of arranging a substrate in a chamber without holding the substrate to form an intermediate layer on the entire surface of the substrate. However, in this case, when it is necessary to heat the substrate, a manufacturing apparatus becomes complicated.

Therefore, as described above, for example, a deposition method is considered which swings or rotates a substrate to change the position of the substrate in the sputtering direction of a film forming material during deposition. In this method, a film is formed on the front surface and the side surface of the substrate by one process and a film is formed on the rear surface of the substrate by the next deposition process. That is, it is possible to form a film on the entire surface of the substrate by a total of two processes.

In addition, the following method may be used: a method of generating a film forming material from a large source, changing the position where the material is generated, and forming a film on the entire surface of a substrate without moving the substrate. An example of the method is an RF sputtering method that swings or rotates a magnet to move the position of a magnet of a cathode in a target during deposition. When the RF sputtering method is used to form a film, both the substrate and the cathode may be moved. In addition, the cathode, which is a material source, may be provided in the vicinity of the substrate to supply plasma so as to surround the substrate without supplying beam-shaped plasma to the substrate. In this case, it is possible to simultaneously form a film on the front surface and the side surface of the substrate.

As a method of generating plasma, any of the following methods may be used: a sputtering method of applying a high voltage with a specific degree of vacuum to generate a discharge as in this embodiment; a PLD method of radiating a laser beam with high energy density to generate plasma; and a PED method of radiating an electron beam to generate plasma. Among the above-mentioned methods, the sputtering method is preferable since it is the simplest and is suitable for mass production. When a DC sputtering method is used, the surface of a target is charged up, and the deposition rate is likely to be unstable. Therefore, it is preferable to use a pulsed DC sputtering method or an RF sputtering method.

In the sputtering process according to this embodiment, a sputtering method is used to form an intermediate layer on the substrate subjected to reverse sputtering in the pre-process. Therefore, there is no lattice mismatch between the substrate and a group-III nitride semiconductor crystal, and it is possible to obtain an intermediate layer having high and stable crystallinity.

Next, the structure of the light-emitting device 1 obtained by the method of manufacturing a group-III nitride compound semiconductor light-emitting device according to this embodiment that includes the pre-process and the sputtering process will be described in detail.

### [Substrate]

In this embodiment, the substrate 11 may be formed of any material as long as a group-III nitride compound semiconductor crystal can be epitaxially grown on the surface of the substrate. For example, the substrate may be formed of any of the following materials: sapphire, SiC, silicon, zinc oxide, magnesium oxide, manganese oxide, zirconium oxide, manganese zinc iron oxide, magnesium aluminum oxide, zirconium boride, gallium oxide, indium oxide, lithium gallium oxide, lithium aluminum oxide, neodymium gallium oxide, lanthanum strontium aluminum tantalum oxide, strontium titanium oxide, titanium oxide, hafnium, tungsten, and molybdenum. Among these materials, particularly, sapphire is preferable.

When the intermediate layer is formed without using ammonia, an underlying layer, which will be described below, is formed by a method of using ammonia, and an oxide substrate or a metal substrate made of a material that contacts ammonia at a high temperature to be chemically modified among the substrate materials is used, the intermediate layer according to this embodiment also serves as a coating layer. Therefore, this structure is effective in preventing the chemical modification of the substrate.

### [Intermediate Layer]

In the laminated semiconductor 10 according to this embodiment, the single crystal intermediate layer 12 made of a group-III nitride compound is formed on the substrate 11 by the sputtering method. The intermediate layer 12 is formed by the sputtering method that activates the reaction between a metal raw material and gas including a group-V element in plasma.

The intermediate layer 12 needs to cover 60% or more, preferably, 80% or more of the front surface 11a of the substrate 11. It is preferable that the intermediate layer 12 be formed so as to cover 90% or more of the front surface of the substrate 11, in terms of the function of a coating layer of the substrate 11. It is most preferable that the intermediate layer 12 be formed so as to cover the entire front surface 11a of the substrate 11 without any gap.

When the surface of the substrate 11 is exposed without being covered by the intermediate layer 12, a portion of the underlying layer 14a formed on the intermediate layer 12 and the other portion of the underlying layer 14a directly formed on the substrate 11 have different lattice constants. Therefore, a uniform crystal is not obtained, and a hillock or a pit occurs.

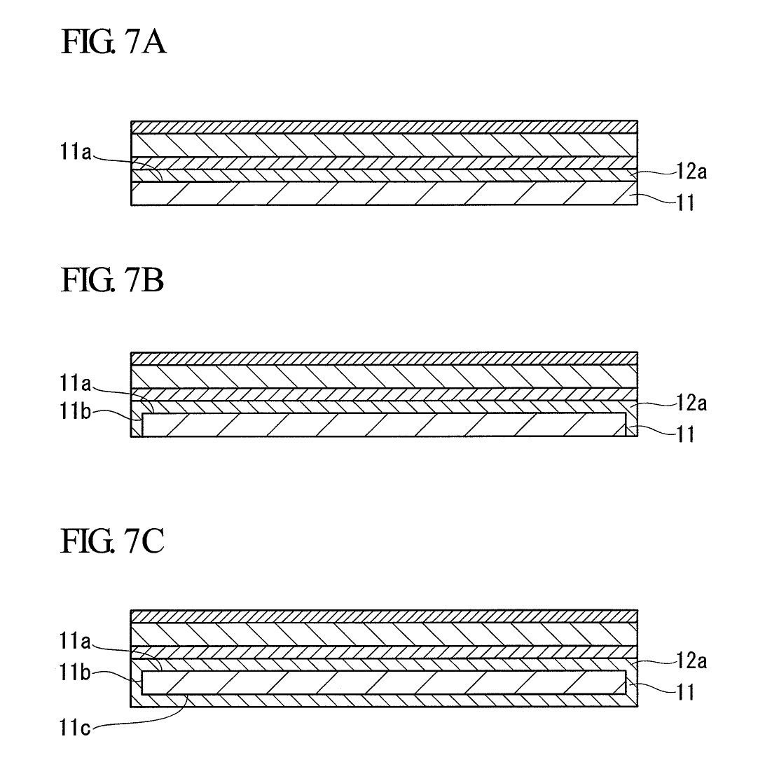

In the sputtering process, when an intermediate layer is formed the substrate 11, as shown in FIG. 7A, an intermediate layer 12a may be formed so as to cover only the front surface 11a of the substrate 11. As shown in FIG. 7B, an intermediate layer 12b may be formed so as to cover the front surface 11a and the side surface 11b of the substrate 11. As shown in FIG. 7C, it is most preferable that an intermediate layer 12c be formed so as to cover the front surface 11a, the side surface 11b, and the rear surface 11c of the substrate 11, in terms of the function of a coating layer.

As described above, in an MOCVD method, in some cases, a raw material gas contacts the side surface or the rear surface of the substrate. Therefore, when layers made of group-III nitride compound semiconductor crystals, which will be described below, are formed by the MOCVD method, in order to prevent the reaction between the raw material gas and the substrate, it is preferable that the intermediate layer 12c shown in FIG. 7C be formed to protect the side surface and the rear surface of the substrate.

The crystal of a group-III nitride compound forming the intermediate layer has a hexagonal crystal structure, and it is possible to control the deposition conditions to form a single crystal film. In addition, it is possible to change the crystal of the group-III nitride compound into a columnar crystal that is composed of a texture having a hexagonal column as a base by controlling the deposition conditions. The columnar crystal means a crystal which has a columnar shape in a longitudinal sectional view, and a crystal grain boundary is fanned between adjacent crystal grains.

It is preferable that the intermediate layer 12 have a single crystal structure in terms of a buffer function. As described above, the crystal of the group-III nitride compound has a hexagonal crystal structure, and forms a texture having a hexagonal column as a base. The crystal of the group-III nitride compound can be grown in the in-plane direction to form a single crystal structure by controlling the deposition conditions. Therefore, when the intermediate layer 12 having the single crystal structure is formed on the substrate 11, the buffer function of the intermediate layer 12 works effectively, and a group-III nitride semiconductor layer formed on the intermediate layer becomes a crystal film having good alignment and crystallinity.

When the intermediate layer 12 is formed of a polycrystal, which is an aggregate of columnar crystals, the average of the widths of the grains of the columnar crystals is preferably in the range of 1 to 100 nm, more preferably, 1 to 70 nm in terms of the function of a buffer layer. When the intermediate layer is formed of an aggregate of columnar crystals, in order to improve the crystallinity of a crystal layer made of a group-III nitride compound semiconductor formed on the intermediate layer, it is necessary to appropriately control the width of the grain of each columnar crystal. Specifically, it is preferable that the average of the widths of the crystal grains be within the above-mentioned range. The width of the grain of each columnar crystal can be easily measured from a cross-section TEM photograph.

When the intermediate layer is formed of a polycrystal, it is preferable that the grain of each crystal have a substantially columnar shape and the intermediate layer be formed of an aggregate of cylindrical grains.

In the present invention, the width of the grain is the distance between the interfaces of crystals when the intermediate layer is an aggregate of cylindrical grains. When the grains are scattered in island shapes, the width of the grain means the length of a diagonal line of the largest portion of the surface of the crystal grain coming into contact with the surface of the substrate.

The thickness of the intermediate layer 12 is preferably in the range of 10 to 500 nm, more preferably, 20 to 100 nm.

If the thickness of the intermediate layer 12 is less than 10 nm, a sufficient buffer function is not obtained. On the other hand, if the thickness of the intermediate layer 12 is more than 500 nm, the intermediate layer serves as a buffer layer, but the deposition time is increased, which results in low productivity.

The intermediate layer 12 is preferably formed of a composition including Al, more preferably, a composition including AlN.

The intermediate layer 12 may be formed of any group-III nitride compound semiconductor that is represented by the general formula AlGaInN. In addition, the intermediate layer 12 may be formed of a material including a group-V element, such as As or P.

It is preferable that the intermediate layer 12 be formed of GaAlN as a composition including Al. In this case, it is preferable that the content of Al be 50% or more.

In addition, it is preferable that the intermediate layer 12 be formed of AlN when the intermediate layer is formed of an aggregate of columnar crystals. In this case, it is possible to effectively form an aggregate of columnar crystals.

### [Laminated Semiconductor]

As shown in FIG. 1, in the laminated semiconductor 10 according to this embodiment, a light-emitting semiconductor layer including the n-type semiconductor layer 14, the light-emitting layer 15, and the p-type semiconductor layer 16 each made of a nitride compound semiconductor is formed on the substrate 11 with the intermediate layer 12 interposed therebetween.

The n-type semiconductor layer 14 includes at least an underlying layer 14a made of a group-III nitride compound semiconductor, and the underlying layer 14a is formed on the intermediate layer 12.

As described above, a crystal laminated structure having the same function as the laminated semiconductor 10 shown in FIG. 1 can be formed on the underlying layer 14a made of a group-III nitride compound semiconductor. For example, when a semiconductor laminated structure for a light-emitting device is formed, an n-type conductive layer doped with an n-type dopant, such as Si, Ge, or Sn, or a p-type conductive layer doped with a p-type dopant, such as Mg, may be formed. For example, a light-emitting layer may be formed of InGaN, and a clad layer may be formed of AlGaN. As such, a group-III nitride semiconductor crystal layer having an additional function can be formed on the underlying layer 14a to manufacture a wafer having a semiconductor laminated structure. The wafer is used to manufacture a light-emitting diode, a laser diode, or an electronic device.

Next, the laminated semiconductor 10 will be described in detail.

As the nitride compound semiconductors, various kinds of gallium nitride compound semiconductors have been known which are represented by the general formula Al_{X}Ga_{Y}In_{Z}N_{1-A}M_{A} (0≦X≦1, 0≦Y≦1, 0≦Z≦1, and X+Y+Z=1. M indicates a group-V element different from nitrogen (N) and 0≦A≦1). The present invention can also use any kind of gallium nitride compound semiconductor represented by the general formula Al_{X}Ga_{Y}In_{Z}N_{1-A}M_{A} (0≦X≦1, 0≦Y≦1, 0≦Z≦1, and X+Y+Z=1. M indicates a group-V element different from nitrogen N and 0≦A≦1) in addition to the known gallium nitride compound semiconductors.

The gallium nitride compound semiconductor may include group-III elements other than Al, Ga, and In, and it may include elements, such as Ge, Si, Mg, Ca, Zn, Be, P, As, and B, if necessary. In addition, it may include dopants, a raw material, and a very small amount of dopants contained in a reaction coil material that are necessarily contained depending on the deposition conditions, in addition to the elements that are intentionally added.

A method of growing the gallium nitride compound semiconductor is not particularly limited. For example, any method of growing a nitride compound semiconductor, such as an MOCVD (metal organic chemical vapor deposition) method, an HYPE (hydride vapor phase epitaxy) method, or an MBE (molecular beam epitaxy) method, may be used to grow the nitride compound semiconductor. The MOCVD method is preferable in terms of the control of the thickness of a film and mass production. In the MOCVD method, hydrogen (H₂) or nitrogen (N₂) is used as a carrier gas, trimethylgallium (TMG) or triethylgallium (TEG) is used as a Ga source, which is a group-III element, trimethylaluminum (TMA) or triethylaluminum (TEA) is used as an Al source, trimethylindium (TMI) or triethylindium (TEI) is used as an In source, and ammonia (NH₃) or hydrazine (N₂H₄) is used as a nitrogen (N) source, which is a group-V element. In addition, for example, Si-based materials, such as monosilane (SiH₄) and disilane (Si₂H₆), and Ge-based materials, that is, organic germanium compounds, such as germane (GeH₄), tetramethylgermanium ((CH₃)₄Ge), and tetraethylgermanium ((C₂H₅)₄Ge), are used as n-type dopants. In the MBE method, elemental germanium may be used as a dopant source. Mg-based materials, such as bis-cyclopentadienylmagnesium (Cp₂Mg) and bisethylcyclopentadienyl magnesium (EtCp₂Mg), are used as p-type dopants.

### <N-Type Semiconductor Layer>

The n-type semiconductor layer 14 is generally formed on the intermediate layer 12, and includes the underlying layer 14a, an n-type contact layer 14b, and an n-type clad layer 14c. The n-type contact layer may also serve as the underlying layer and/or the n-type clad layer. The underlying layer may also serve as the n-type contact layer and/or the n-type clad layer.

### <Underlying Layer>

The underlying layer 14a is formed of a group-III nitride compound semiconductor, and is formed on the substrate 11.

The underlying layer 14a may be formed of a material different from the material forming the intermediate layer 12 formed on the substrate 11. The underlying layer 14a is preferably formed of Al_{X}Ga_{1-X}N (0≦x≦1, preferably, 0≦x≦0.5, more preferably, 0≦x≦0.1).

The underlying layer 14a is formed of a group-III nitride compound including Ga, that is, a GaN compound semiconductor. In particular, it is preferable that the underlying layer be formed of AlGaN or GaN.

It is necessary to form a dislocation loop by migration such that the underlying layer 14a does not succeed to the crystallinity of the intermediate layer 12 when the intermediate layer 12 is formed of an aggregate of columnar crystals made of AlN. For example, the underlying layer is formed of a GaN-based compound semiconductor including Ga. In particular, it is preferable that the underlying layer be formed of AlGaN or GaN.

The thickness of the underlying layer is preferably not less than 0.1 μm, more preferably, not less than 0.5 μm, most preferably, not less than 1 μm. If the thickness is greater than the above-mentioned range, it is easy to obtain an Al_{X}Ga_{1-X}N layer with high crystallinity.

The underlying layer 14a may be doped with an n-type dopant in the concentration range of 1×10¹⁷ to 1×10¹⁹/cm³, if necessary, or the underlying layer 14a may be undoped (<1×10¹⁷/cm³). It is preferable that the underlying layer 14a be undoped in order to maintain high crystallinity. For example, Si, Ge, and Sn, preferably, Si and Ge are used as the n-type dopant, but the present invention is not limited thereto.

When a conductive substrate is used as the substrate 11, the underlying layer 14a is doped with a dopant, and the underlying layer 14a has a layer structure that allows a current to flow in the longitudinal direction. In this way, electrodes can be formed on both surfaces of a chip of the light-emitting device.

When an insulating substrate is used as the substrate 11, a chip structure in which electrodes are formed on one surface of the chip of the light-emitting device is used. Therefore, it is preferable that the underlying layer 14a formed on the substrate 11 with the intermediate layer 12 interposed therebetween be undoped, in order to improve the crystallinity.

### (Method of Forming Underlying Layer)

Next, a method of forming the underlying layer according to this embodiment will be described.

In this embodiment, after the intermediate layer 12 is formed on the substrate 11 by the above-mentioned method, the underlying layer 14a made of a group-III nitride compound semiconductor can be formed on the intermediate layer. Before the underlying layer 14a is formed, it is not particularly necessary to perform an annealing process. However, in general, when a group-III nitride compound semiconductor film is formed by a chemical vapor deposition method, such as MOCVD, MBE, or VPE, a temperature increasing process and a temperature stabilizing process not involving film deposition are needed, and during these processes, a group-V raw material gas is generally introduced into the chamber. As a result, an annealing effect is obtained.

In this case, a general gas may be used as a carrier gas, without any restrictions, or hydrogen or nitrogen that is generally used in a chemical vapor deposition method, such as MOCVD, may be used as the carrier gas. However, when hydrogen is used as the carrier gas, the crystallinity of the underlying layer or the flatness of a crystal surface may be damaged due to a temperature increase in relatively active hydrogen. Therefore, it is preferable to shorten the process time.

A method of forming the underlying layer 14a is not particularly limited. As described above, any crystal growing method may be used as long as it can form a dislocation loop. In particular, MOCVD, MBE, or VPE is preferable to form a film having high crystallinity since it can generate the above-mentioned migration. Among them, MOCVD is more preferable since it can form a film having the highest crystallinity.

In addition, a sputtering method may be used to form the underlying layer 14a made of a group-III nitride compound semiconductor. When the sputtering method is used, it is possible to simplify the structure of an apparatus, as compared to MOCVD or MBE.

When the underlying layer 14a is formed by the sputtering method, it is preferable to use a reactive sputtering method that introduces a group-V raw material into a reactor.

As described above, generally, in the sputtering method, as the degree of purity of a target material is increased, the quality of a thin film, such as the crystallinity of a thin film, is improved. When the underlying layer 14a is formed by the sputtering method, a group-III nitride compound semiconductor may be used as a target material, serving as a raw material, and sputtering may be performed in inert gas plasma, such as Ar gas plasma. In the reactive sputtering method, a group-III elemental metal or a mixture thereof used as a target material can have a purity that is higher than that of a group-III nitride compound semiconductor. Therefore, the reactive sputtering method can improve the crystallinity of the underlying layer 14a.

The temperature of the substrate 11 when the underlying layer 14a is formed, that is, the deposition temperature of the underlying layer 14a is preferably not lower than 800° C., more preferably, not lower than 900° C., most preferably, not lower than 1000° C. When the temperature of the substrate 11 is high during the deposition of the underlying layer 14a, atoms are more likely to migrate, and it is easy to form a dislocation loop. In addition, the temperature of the substrate 11 when the underlying layer 14a is formed needs to be lower than the decomposition temperature of crystal. For example, it is preferable that the temperature of the substrate be lower than 1200° C. When the temperature of the substrate 11 during the deposition of the underlying layer 14a is in the above-mentioned range, it is possible to obtain the underlying layer 14a having high crystallinity.

In addition, it is preferable that the internal pressure of an MOCVD furnace be in the range of 15 to 40 kPa.

### <N-Type Contact Layer>

It is preferable that the n-type contact layer 14b be formed of Al_{X}Ga_{1-X}N (0≦x≦1, preferably, 0≦x≦0.5, more preferably, 0≦x≦0.1), similar to the underlying layer 14a. The n-type contact layer is preferably doped with an n-type dopant in the concentration range of 1×10¹⁷ to 1×10¹⁹/cm³, more preferably, 1×10¹⁸ to 1×10¹⁹/cm³, in order to maintain good ohmic contact with the negative electrode, prevent the occurrence of cracks, and maintain high crystallinity. For example, Si, Ge, and Sn, preferably, Si and Ge are used as the n-type dopant, but the present invention is not limited thereto. The deposition temperature of the n-type contact layer is the same as that of the underlying layer.

It is preferable that the gallium nitride compound semiconductors forming the underlying layer 14a and the n-type contact layer 14b have the same composition. The sum of the thicknesses of the underlying layer and the n-type contact layer is preferably in the range of 1 to 20 μm, preferably, 2 to 15 μm, most preferably, 3 to 12 μm. When the thickness is in the above-mentioned range, it is possible to maintain the crystallinity of the semiconductor at a high level.

It is preferable to provide the n-type clad layer 14c between the n-type contact layer 14b and the light-emitting layer 15, which will be described below. The n-type clad layer 14c makes it possible to restore the unevenness of the outer surface of the n-type contact layer 14b. The n-type clad layer 14c may be formed of, for example, AlGaN, GaN, or GaInN. In addition, a heterojunction structure of these layers or a superlattice structure of a plurality of layers may be used. When the n-type clad layer is formed of GaInN, it is preferable that the band gap of GaInN of the n-type clad layer be larger than that of GaInN of the light-emitting layer 15.

### <N-Type Clad Layer>

The thickness of the n-type clad layer 14c is not particularly limited, but is preferably in the range of 5 to 500 nm, more preferably, 5 to 100 nm.

The n-type dopant concentration of the n-type clad layer 14c is preferably in the range of 1×10¹⁷ to 1×10²⁰/cm³, more preferably, 1×10¹⁸ to 1×10¹⁹/cm³.

If the dopant concentration is within the above-mentioned range, it is possible to maintain high crystallinity and reduce the driving voltage of a light-emitting device.

### <P-Type Semiconductor Layer>

In general, the p-type semiconductor layer 16 includes a p-type clad layer 16a and a p-type contact layer 16b. However, the p-type contact layer may also serve as the p-type clad layer.

### <P-Type Clad Layer>

The p-type clad layer 16a is not particularly limited as long as it has a composition that has a band gap energy higher than that of the light-emitting layer 15 and it can confine carriers in the light-emitting layer 15. It is preferable that the p-type clad layer 16a be formed of Al_{d}Ga_{1-d}N (0≦d≦0.4, preferably, 0.1≦d≦0.3). When the p-type clad layer 16a is formed of AlGaN, it is possible to confine carriers in the light-emitting layer 15. The thickness of the p-type clad layer 16a is not particularly limited, but is preferably in the range of 1 to 400 nm, more preferably, 5 to 100 nm. The p-type dopant concentration of the p-type clad layer 16a is preferably in the range of 1×10¹⁸ to 1×10²¹/cm³, more preferably, 1×10¹⁹ to 1×10²⁰/cm³. This p-type dopant concentration range makes it possible to obtain a good p-type crystal without deteriorating crystallinity.

### <P-Type Contact Layer>

The p-type contact layer 16b is composed of a gallium nitride compound semiconductor layer containing at least AlₑGa₁₋ₑN (0≦e<0.5, preferably, 0≦e≦0.2, more preferably, 0≦e≦0.1). When the Al composition is within the above range, it is possible to maintain high crystallinity and low ohmic contact resistance with a p-type ohmic electrode (see a transparent electrode 17, which will be described below).

When the p-type dopant concentration is in the range of 1×10¹⁸ to 1×10²¹/cm³, it is possible to maintain low ohmic contact resistance, prevent the occurrence of cracks, and maintain high crystallinity. It is more preferable that the p-type dopant concentration be in the range of 5×10¹⁹ to 5×10²⁰/cm³.

For example, the p-type dopant may be Mg, but is not limited thereto.

The thickness of the p-type contact layer 16b is not particularly limited, but is preferably in the range of 10 to 500 nm, more preferably, 50 to 200 nm. This thickness range makes it possible to improve emission power.

### <Light-Emitting Layer>

The light-emitting layer 15 is formed between the n-type semiconductor layer 14 and the p-type semiconductor layer 16. As shown in FIG. 1, the light-emitting layer is formed by alternately laminating barrier layers 15a made of a gallium nitride compound semiconductor and well layers 15b made of a gallium nitride compound semiconductor including indium, and the bather layers 15a are arranged so as to contact the n-type semiconductor layer 14 and the p-type semiconductor layer 16.

In the structure shown in FIG. 1, the light-emitting layer 15 includes six barrier layers 15a and five well layers 15b alternately formed. The barrier layers 15a are arranged at the uppermost and lowermost sides of the light-emitting layer 15, and the well layer 15b is arranged between the bather layers 15a.

The barrier layer 15a is preferably formed of, for example, a gallium nitride compound semiconductor, such as Al_{c}Ga_{1-c}N (0≦c<0.3), having a band gap energy that is higher than that of the well layer 15b that is formed of a gallium nitride compound semiconductor including indium.

The well layer 15b may be formed of a gallium indium nitride, such as Ga₁₋ₛInₛN (0<s<0.4), as the gallium nitride compound semiconductor including indium.

### <Transparent Positive Electrode>

The transparent positive electrode 17 is a transparent electrode formed on the p-type semiconductor layer 16 of the laminated semiconductor 10 manufactured in this way.

The material forming the transparent positive electrode 17 is not particularly limited, but the transparent positive electrode 17 may be formed of, for example, ITO (In₂O₃—SnO₂), AZO (ZnO—Al₂O₃), IZO (In₂O₃—ZnO), or GZO (ZnO—Ga₂O₃) by a known means. In addition, the transparent positive electrode 17 may have any known structure, without any restrictions.

The transparent positive electrode 17 may be formed so as to cover the entire surface of the p-type semiconductor layer 16 doped with Mg, or it may be formed in a lattice shape or a tree shape. After the transparent positive electrode 17 is formed, a thermal annealing process may be performed to form an alloy or make the electrode transparent, or the thermal annealing process may not be performed.

### <Positive Electrode Bonding Pad and Negative Electrode>

A positive electrode bonding pad 18 is an electrode that is formed on the transparent positive electrode 17.

The positive electrode bonding pad 18 may be formed of various known materials, such as Au, Al, Ni, and Cu. However, the known materials and the structure of the positive electrode bonding pad are not particularly limited.

It is preferable that the thickness of the positive electrode bonding pad 18 be in the range of 100 to 1000 nm. In addition, the bonding pad has characteristics that, as the thickness thereof increases, bondability is improved. Therefore, it is preferable that the thickness of the positive electrode bonding pad 18 be greater than or equal to 300 nm. In addition, it is preferable that the thickness of the positive electrode bonding pad be less than or equal to 500 nm in order to reduce manufacturing costs.

A negative electrode 19 is formed so as to come into contact with the n-type contact layer 14b of the n-type semiconductor layer 14 in the semiconductor layer, which is a laminate of the n-type semiconductor layer 14, the light-emitting layer 15, and the p-type semiconductor layer 16 sequentially formed on the substrate 11.

Therefore, when the negative electrode bonding pad 17 is formed, the light-emitting layer 15, the p-type semiconductor layer 16, and the n-type semiconductor layer 14 are partially removed to form an exposed region 14d of the n-type contact layer 14b and the negative electrode 19 is formed on the exposed region.

The negative electrode 19 may be formed of any material whose composition and structure have been known, and the negative electrode can be formed by a means that has been known in this technical field.

As described above, the method of manufacturing a group-III nitride compound semiconductor light-emitting device according to this embodiment includes the pre-process that performs plasma processing on the substrate 11 and the sputtering process that forms the intermediate layer 12 on the substrate 11 using a sputtering method after the pre-process. In this way, the intermediate layer 12 having a uniform crystal structure is formed on the substrate 11, and there is no lattice mismatch between the substrate 11 and a semiconductor layer made of a group-III nitride semiconductor. Therefore, it is possible to effectively grow a group-III nitride semiconductor having high crystallinity on the substrate 11. As a result, it is possible to obtain the group-III nitride compound semiconductor light-emitting device 1 having high productivity and good emission characteristics.

As described above, as a mechanism for performing reverse sputtering on the substrate 11 to obtain the above-mentioned effects, the following is used: a mechanism of removing a contaminant adhered to the surface of the substrate 11 using chemical reaction in plasma gas such that a crystal lattice match between the surface of the substrate 11 and a group-III nitride compound is achieved.

According to the manufacturing method according to this embodiment, it is possible to perform the pre-process such that the substrate has good surface conditions by the above-mentioned reaction, without damaging the surface of the substrate, unlike a so-called bombardment method that removes a contaminant from the surface of the substrate by physical collision using an Ar gas.

The structures of the substrate, the intermediate layer, and the underlying layer according to this embodiment are not limited to a group-III nitride compound semiconductor light-emitting device. For example, the structures may be applied to the case in which a raw material gas is likely to react with the substrate at a high temperature when deposition is performed using materials having similar lattice constants.

### [Lamp]

A lamp can be formed by combining the group-III nitride compound semiconductor light-emitting device according to the present invention with a phosphor by a known means. In recent years, a technique for combining a light-emitting device with a phosphor to change the color of emission light has been known, and the lamp according to the present invention can adopt the technique without any restrictions.

For example, it is possible to emit light having a long wavelength from the light-emitting device by appropriately selecting a phosphor used for the lamp. In addition, it is possible to achieve a lamp emitting white light by mixing the emission wavelength of the light-emitting device and a wavelength converted by the phosphor.

In addition, the light-emitting device according to the present invention may be used for various types of lamps, such as a general-purpose bullet-shaped lamp, a side view lamp for a backlight of a portable device, and a top view lamp used for a display device.

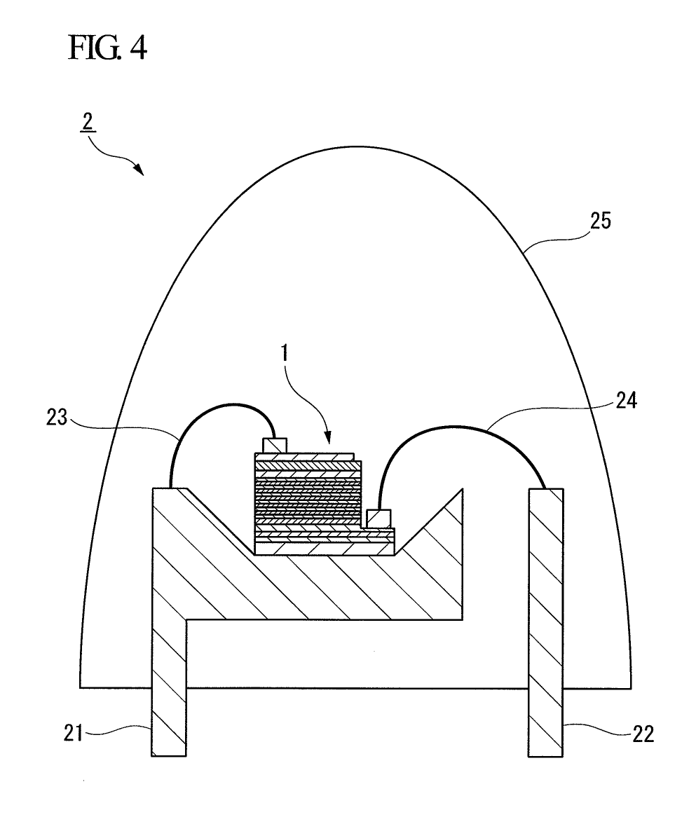

For example, as shown in FIG. 4, when the group-III nitride compound semiconductor light-emitting device 1 having electrodes formed on the same surface is mounted to a bullet-shaped lamp, the light-emitting device 1 is bonded to one (a frame 21 in FIG. 4) of two frames. In addition, the negative electrode (see reference numeral 19 in FIG. 3) of the light-emitting device 1 is bonded to a frame 22 by a wire 24, and the positive electrode bonding pad (see reference numeral 18 in FIG. 3) of the light-emitting device 1 is bonded to a frame 21 by a wire 23. Then, the periphery of the light-emitting device 1 is sealed by a mold 25 made of a transparent resin. In this way, it is possible to manufacture a bullet-shaped lamp 2 shown in FIG. 4.

The group-III nitride compound semiconductor light-emitting device according to the present invention can be applied to manufacture, for example, photoelectric conversion devices, such as a laser device and a light-receiving device, and electronic devices, such as an HBT and an HEMT, in addition to the light-emitting device.

### EXAMPLES

Next, the group-III nitride compound semiconductor light-emitting device and the method of manufacturing the group-III nitride compound semiconductor light-emitting device according to the present invention will be described in detail with reference to Examples, but the present invention is not limited to Examples.

### Example 1

In Example 1, an aggregate of columnar crystals made of AlN was formed as the intermediate layer 12 on the c-plane of the substrate 11 made of sapphire by an RF sputtering method, and an undoped GaN semiconductor layer was formed as the underlying layer 14a on the intermediate layer by an MOCVD method, thereby manufacturing a sample according to Example 1.

The sapphire substrate 11 whose one surface was polished into a mirror surface suitable for epitaxial growth was put into a sputtering apparatus, without being subjected to a pre-process, such as a wet process. The sputtering apparatus that had a radio frequency power supply and a mechanism capable of changing the position of a magnet in a target was used.

Then, the substrate 11 was heated up to a temperature of 750° C. in the sputtering apparatus and only nitrogen gas was introduced into the sputtering apparatus at a flow rate of 30 sccm, and the internal pressure of the chamber is maintained at 0.08 Pa. Then, an RF bias of 50 W was applied to the substrate 11 and the substrate 11 is exposed in nitrogen plasma (reverse sputtering). At that time, the temperature of the substrate 11 was 500° C. and the process time was 200 seconds.

Then, argon and nitrogen gases were introduced into the sputtering apparatus while maintaining the temperature of the substrate 11 at 500° C. Then, an RF bias of 2000 W was supplied to an Al target to form the intermediate layer 12 made of AlN on the sapphire substrate 11 under the following conditions: an internal pressure of a furnace of 0.5 Pa; a flow rate of Ar gas of 15 sccm; and a flow rate of nitrogen gas of 5 sccm (the percentage of nitrogen in the entire gas was 75%). In this case, the deposition rate was 0.12 m/s.

The magnet in the target was swung both during the reverse sputtering of the substrate 11 and during deposition.

An AlN film (intermediate layer 12) was formed with a thickness of 50 nm at a predetermined deposition rate for a predetermined time, and then a plasma operation stopped to reduce the temperature of the substrate 11.

Then, the substrate 11 having the intermediate layer 12 formed thereon was taken out from the sputtering apparatus and then put into an MOCVD furnace. Then, a sample having a GaN layer (group-III nitride semiconductor) formed thereon was manufactured by an MOCVD method as follows.

First, the substrate 11 was put into a reactive furnace. The substrate 11 was loaded on a carbon susceptor for heating in a glove box filled with a nitrogen gas. Then, the nitrogen gas was introduced into the furnace, and a heater was operated to increase the temperature of the substrate 11 to 1150° C. After it was checked that the temperature of the substrate 11 was stabilized at 1150° C., a valve for an ammonia pipe was opened to introduce ammonia into the furnace. Then, hydrogen including the vapor of TMGa was supplied into the furnace to deposit a GaN-based semiconductor for forming the underlying layer 14a on the intermediate layer 12 formed on the substrate 11. The amount of ammonia was adjusted such that the ratio of V to III was 6000. The GaN-based semiconductor was grown after about one hour, and a valve for a TMGa pipe was switched to stop the supply of a raw material into the reactive furnace, thereby stopping the growth of the semiconductor. After the growth of the GaN-based semiconductor ended, the heater was turned off to reduce the temperature of the substrate 11 to room temperature.

In this way, the intermediate layer 12 that had a columnar crystal structure and was made of AlN was formed on the substrate 11 made of sapphire, and the undoped underlying layer 14a that was made of a GaN-based semiconductor and had a thickness of 2 μm was formed on the intermediate layer, thereby manufacturing a sample according to Example 1. The substrate had a colorless transparent mirror surface.

The X-ray rocking curve (XRC) of the undoped GaN layer obtained by the above-mentioned method was measured by a four-crystal X-ray diffractometer (PANalytical's X′pert).

In the measuring process, a Cuβ-line X-ray generator was used as a light source and the measurement was performed for (0002) planes, which were symmetric planes, and (10-10) planes, which were asymmetric planes. Generally, in the case of a group-III nitride compound semiconductor, the half width of the XRC spectrum of the (0002) plane is used as an index for the flatness (mosaicity) of crystal and the half width of the XRC spectrum of the (10-10) plane is used as an index for the dislocation density (twist). As a result of the measurement, the (0002) plane of the undoped GaN layer formed by the manufacturing method according to the present invention had a half width of 100 arcseconds and the (10-10) plane thereof had a half width of 320 arcseconds.

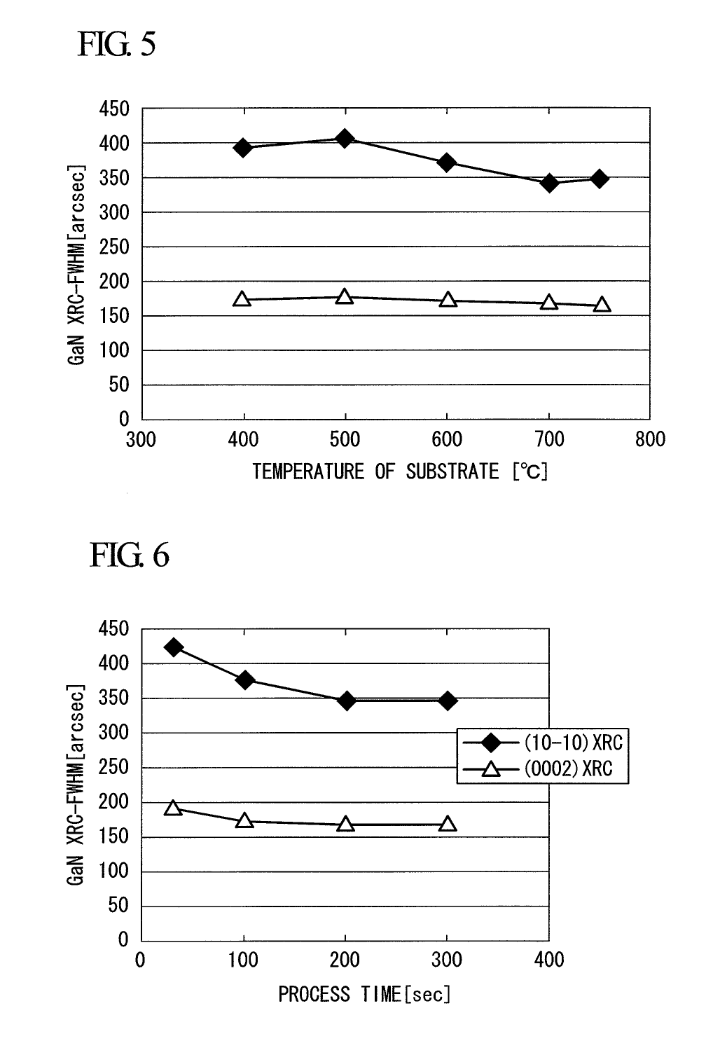

The intermediate layer 12 and the underlying layer 14a were formed under the same deposition conditions. Then, among the deposition conditions of the intermediate layer 12, the substrate temperature and the process time were changed in the pre-process. Data for the X-ray half width of a GaN crystal is shown in FIGS. 5 and 6.

### Example 2

In Example 2, a Ge-doped n-type contact layer 14b was formed on an undoped GaN crystal (underlying layer 14a) which was formed with a thickness of 6 μm under the same conditions as those in Example 1. Then, various layers were formed on the n-type contact layer. Finally, an epitaxial wafer (laminated semiconductor 10) having an epitaxial layer structure for the group-III nitride compound semiconductor light-emitting device shown in FIG. 1 was manufactured.

The epitaxial wafer had a laminated structure in which the buffer layer 12 that was made of AlN having a columnar crystal structure, the underlying layer 14a that was made of undoped GaN with a thickness of 6 μm, the n-type contact layer 14b that had an electron concentration of 1×10¹⁹ cm⁻³ and was made of Ge-doped GaN with a thickness of 2 μm, an n-type In_{0.1}Ga_{0.9}N clad layer (n-type clad layer 14c) that had an electron concentration of 1×10¹⁸ cm⁻³ and a thickness of 20 nm, the light-emitting layer 15 (which has a multiple quantum well structure), and the p-type semiconductor layer 16 were sequentially formed on the sapphire substrate 11 having the c-plane by the same deposition method as that according to Example 1. The light-emitting layer 15 had a laminated structure in which six GaN barrier layers 15a each having a thickness of 16 nm and five undoped In_{0.2}Ga_{0.8}N well layers 15b each having a thickness of 3 nm were alternately laminated, and two of the GaN barrier layers were arranged at the uppermost and lowermost sides of the light-emitting layer. The p-type semiconductor layer 16 was formed by laminating a Mg-doped p-type Al_{0.1}Ga_{0.9}N clad layer 16a with a thickness of 5 nm and a Mg-doped p-type Al_{0.02}Ga_{0.98}N contact layer 16b with a thickness of 200 nm.

During the manufacture of the wafer including an epitaxial layer having the semiconductor light-emitting device structure, the intermediate layer 12 made of AlN and having a columnar crystal structure was formed on the substrate 11 by the same processes as those in Example 1.

Then, the semiconductor laminated structure was formed by the same process as that forming the underlying layer 14a using the same MOCVD apparatus.

In this way, an epitaxial wafer having an epitaxial layer structure for a semiconductor light-emitting device was manufactured. The Mg-doped p-type Al_{0.02}Ga_{0.98}N contact layer 16b showed p-type characteristics without being subjected to an annealing process for activating p-type carriers.

Then, the epitaxial wafer (see the laminated semiconductor 10 shown in FIG. 1) having the epitaxial layer structure formed on the sapphire substrate 11 was used to manufacture a light-emitting diode (see the light-emitting device 1 shown in FIGS. 2 and 3), which is a kind of semiconductor light-emitting device.

First, the transparent positive electrode 17 made of ITO and the positive electrode bonding pad 18 having a laminated structure of titanium, aluminum, and gold layers formed in this order on the surface of the transparent positive electrode 17 were sequentially formed on the surface of the Mg-doped p-type Al_{0.02}Ga_{0.98}N contact layer 16b of the wafer by a known photolithography method. Then, dry etching was performed on a portion of the wafer to expose the exposed region 14d from the n-type contact layer 14b. Then, the negative electrode 19 having a four-layer structure of Ni, Al, Ti, and Au layers was formed on the exposed region 14d, thereby forming the electrodes shown in FIGS. 2 and 3 on the wafer.

The rear surface of the substrate 11 of the wafer having the electrodes formed on the p-type semiconductor layer and the n-type semiconductor layer was ground and polished into a mirror surface, and then the wafer was cut into individual square chips each having a 350 μm square. Then, the chip was mounted to a lead frame with each electrode facing upward, and then connected to the lead frame by gold wires, thereby obtaining a semiconductor light-emitting device. A forward current of 20 mA was applied between the positive electrode bonding pad 18 and the negative electrode 19 of the semiconductor light-emitting device (light-emitting diode) to measure a forward voltage. As a result, the forward voltage was 3.0 V. In addition, an emission state was observed through the p-side transparent positive electrode 17. As a result, an emission wavelength was 470 nm and emission power was 15 mW. The emission characteristics of the light-emitting diode were obtained from substantially the entire surface of the manufactured wafer, without any variation.

The reverse sputtering conditions in the pre-process and the measurement results of the X-ray half width and the emission power are shown in the following Table 1.

### Comparative Example 1

In this example, a semiconductor light-emitting device was manufactured, similar to Example 2, except that an intermediate layer made of AlN was formed on the c-plane of a substrate made of sapphire without performing a pre-process using reverse sputtering and the underlying layer 14a made of GaN was formed on the intermediate layer by an MOCVD method.

In the semiconductor light-emitting device according to Comparative Example 1, when a current of 20 mA was applied, a forward voltage was 3.0 V, an emission wavelength was 470 nm, and emission power was 10 mW. As a result, the emission power was lower than that in the semiconductor light-emitting device according to Example 2.

The X-ray rocking curve (XRC) of the GaN underlying layer 14a grown by the method according to Comparative Example 1 was measured. As a result, the half width of the (0002) plane was 300 arcseconds and the half width of the (10-10) plane was 500 arcseconds, which showed that the crystallinity of the underlying layer was deteriorated.

### Examples 3 to 7 and Comparative Examples 2 and 3

In Examples 3 to 7 and Comparative Examples 2 and 3, semiconductor light-emitting devices were manufactured similar to Example 2 except that reverse sputtering was performed in the pre-process under the conditions shown in Table 1.

The reverse sputtering conditions in the pre-process and the measurement results of the X-ray half width and the emission power are shown in Table 1.

### Example 8

In this example, before an intermediate layer was formed on a Si (111) substrate, reverse sputtering was performed on the substrate in Ar plasma as a pre-process, and a single crystal layer made of AlGaN was formed as an intermediate layer on the substrate using a rotary-cathode-type RF sputtering apparatus. In this case, during sputtering, the temperature of the substrate was 500° C.

Then, a Si-doped AlGaN layer was formed as an underlying layer on the intermediate layer using an MOCVD method. Then, the same light-emitting device semiconductor laminated structure as that in Example 2 was formed on the underlying layer. In this case, the content of Al in the intermediate layer was 70%, and the content of Al in the underlying layer was 15%.

Then, after the semiconductor light-emitting device laminated structure was grown by the MOCVD method, the wafer was taken out from a reactor. As a result, the wafer had a mirror surface.

Then, a light-emitting diode chip was obtained from the manufactured wafer by the same method as that in Example 2. In this example, electrodes were provided on the upper and lower surfaces of the semiconductor layer and the substrate.

A forward current of 20 mA was applied between the electrodes to measure a forward voltage. As a result, the forward voltage was 2.9 V. In addition, an emission state was observed through the p-side transparent positive electrode. As a result, an emission wavelength was 460 nm and emission power was 10 mW. The emission characteristics of the light-emitting diode were obtained from substantially the entire surface of the manufactured wafer, without any variation.

The reverse sputtering conditions in the pre-process and the measurement results are shown in Table 1.

### Example 9

In this example, before an intermediate layer was formed on a ZnO (0001) substrate, reverse sputtering was performed on the substrate in O₂ gas plasma as a pre-process, and an intermediate layer made of AlN and having a columnar crystal structure was formed using a DC sputtering apparatus. In this case, during sputtering, the temperature of the substrate was 750° C.

Then, a Ge-doped AlGaN layer was formed as an underlying layer on the intermediate layer using an MOCVD method. Then, the same light-emitting device semiconductor laminated structure as that in Example 2 was formed on the underlying layer.

In this case, the content of Al in the underlying layer was 10%. In this example, the amount of In raw material included in the light-emitting layer was increased in order to manufacture a green LED emitting light in a wavelength of about 525 nm.

Then, after the semiconductor light-emitting device laminated structure was grown by the MOCVD method, the wafer was taken out from a reactor. As a result, the wafer had a mirror surface.

Then, a light-emitting diode chip was obtained from the manufactured wafer by the same method as that in Example 2. In this example, electrodes were provided on the upper and lower surfaces of the semiconductor layer and the substrate.

A forward current of 20 mA was applied between the electrodes to measure a forward voltage. As a result, the forward voltage was 3.3 V. In addition, an emission state was observed through the p-side transparent positive electrode. As a result, green light having an emission wavelength of 525 nm was emitted, and emission power was 10 mW. The emission characteristics of the light-emitting diode were obtained from substantially the entire surface of the manufactured wafer, without any variation.

The reverse sputtering conditions in the pre-process and the measurement results of the X-ray half width and the emission power in Examples 2 to 9 and Comparative Examples 1 to 3 are shown in Table 1.

TABLE 1

| | Pre-process | | | |
|---|---|---|---|---|
| | Reverse | Reverse | X-ray | |
| | sputtering | sputtering | half width | Emission |
| | temperature | time | (0002) | power |
| Example 2 | 500° C. | 200 sec | 50 arcsec | 15 mW |
| Example 3 | 500° C. | 300 sec | 75 arcsec | 15 mW |
| Example 4 | 500° C. | 60 sec | 180 arcsec | 13 mW |
| Example 5 | 300° C. | 200 sec | 200 arcsec | 13 mW |
| Example 6 | 800° C. | 200 sec | 65 arcsec | 15 mW |
| Example 7 | 800° C. | 60 sec | 140 arcsec | 13 mW |
| Example 8 | 500° C. | 200 sec | 200 arcsec | 10 mW |
| Example 9 | 200° C. | 300 sec | 50 arcsec | 10 mW |
| Comparative | — | 0 | 300 arcsec | 10 mW |
| Example 1 | | | | |
| Comparative | 1500° C. | 600 sec | 1000 arcsec | 3 mW |
| Example 2 | | | | |
| Comparative | 500° C. | 10 sec | 400 arcsec | 10 mW |
| Example 3 | | | | |

As can be seen from the above results, in the samples of the group-III nitride compound semiconductor light-emitting devices (Examples 1 to 9) according to the present invention, the half width of the X-ray rocking curve (XRC) of the undoped GaN underlying layer 14a is in the range of 50 to 200 arcseconds. Therefore, the crystallinity of the semiconductor layer made of a group-III nitride compound is significantly improved, as compared to Comparative Examples 1 to 3 in which the half width of the X-ray rocking curve (XRC) of the underlying layer is in the range of 300 to 1000 arcseconds. In addition, in the light-emitting devices according to Examples 2 to 7, the emission power is in the range of 13 to 15 mW, which is considerably higher than the emission power, which is in the range of 3 to 10 mW, of the light-emitting devices according to Comparative Examples 1 to 3.

The above results prove that the group-III nitride compound semiconductor light-emitting device according to the present invention has high productivity and good emission characteristics.

### INDUSTRIAL APPLICABILITY

The present invention can be applied to a group-III nitride compound semiconductor light-emitting device used for, for example, a light-emitting diode (LED), a laser diode (LD), or an electronic device, a method of manufacturing a group-III nitride compound semiconductor light-emitting device, and a lamp.

1. A method of manufacturing a group-III nitride compound semiconductor light-emitting device, comprising:
a pre-process of performing plasma processing on a substrate;
a sputtering process of forming an intermediate layer made of at least a group-III nitride compound on the substrate using a sputtering method after the pre-process; and
a process of sequentially forming an n-type semiconductor layer including an underlying layer, a light-emitting layer, and a p-type semiconductor layer on the intermediate layer.

2. The method of manufacturing a group-III nitride compound semiconductor light-emitting device according to claim 1,
wherein, in the pre-process, gas including nitrogen is introduced into a chamber.

3. The method of manufacturing a group-III nitride compound semiconductor light-emitting device according to claim 2,
wherein, in the pre-process, the partial pressure of the gas including nitrogen introduced into the chamber is in the range of 1×10⁻² Pa to 10 Pa.

4. The method of manufacturing a group-III nitride compound semiconductor light-emitting device according to claim 1,
wherein, in the pre-process, the internal pressure of the chamber is in the range of 0.1 to 5 Pa.

5. The method of manufacturing a group-III nitride compound semiconductor light-emitting device according to claim 1,
wherein the process time of the pre-process is in the range of 30 seconds to 3600 seconds.

6. The method of manufacturing a group-III nitride compound semiconductor light-emitting device according to claim 5,
wherein the process time of the pre-process is in the range of 60 seconds to 600 seconds.

7. The method of manufacturing a group-III nitride compound semiconductor light-emitting device according to claim 1,
wherein, in the pre-process, the temperature of the substrate is in the range of 25° C. to 1000° C.

8. The method of manufacturing a group-III nitride compound semiconductor light-emitting device according to claim 7,
wherein, in the pre-process, the temperature of the substrate is in the range of 300° C. to 800° C.

9. The method of manufacturing a group-III nitride compound semiconductor light-emitting device according to claim 1,
wherein the pre-process and the sputtering process are performed in the same chamber.

10. The method of manufacturing a group-III nitride compound semiconductor light-emitting device according to claim 1,
wherein the plasma processing performed in the pre-process is reverse sputtering.

11. The method of manufacturing a group-III nitride compound semiconductor light-emitting device according to claim 10,
wherein, in the pre-process, an RF power supply is used to generate plasma, thereby performing the reverse sputtering.

12. The method of manufacturing a group-III nitride compound semiconductor light-emitting device according to claim 11,
wherein, in the pre-process, the reverse sputtering is performed by generating nitrogen plasma using the RF power supply.

13. The method of manufacturing a group-III nitride compound semiconductor light-emitting device according to claim 1,
wherein the intermediate layer is formed so as to cover 90% or more of the surface of the substrate.

14. The method of manufacturing a group-III nitride compound semiconductor light-emitting device according to claim 1,
wherein the sputtering process uses a raw material including a group-V element.

15. The method of manufacturing a group-III nitride compound semiconductor light-emitting device according to claim 1,
wherein, in the sputtering process, the intermediate layer is formed by a reactive sputtering method that introduces the raw material including the group-V element into a reactor.

16. The method of manufacturing a group-III nitride compound semiconductor light-emitting device according to claim 14,
wherein the group-V element is nitrogen.

17. The method of manufacturing a group-III nitride compound semiconductor light-emitting device according to claim 14,
wherein ammonia is used as the raw material including the group-V element.

18. The method of manufacturing a group-III nitride compound semiconductor light-emitting device according to claim 1,
wherein, in the sputtering process, the intermediate layer is formed by an RF sputtering method.

19. The method of manufacturing a group-III nitride compound semiconductor light-emitting device according to claim 18,
wherein, in the sputtering process, the intermediate layer is formed by the RF sputtering method while moving a magnet of a cathode.

20. The method of manufacturing a group-III nitride compound semiconductor light-emitting device according to claim 1,
wherein, in the sputtering process, when the intermediate layer is formed, the temperature of the substrate is in the range of 400° C. to 800° C.

21. The method of manufacturing a group-III nitride compound semiconductor light-emitting device according to claim 1,
wherein the underlying layer is formed on the intermediate layer by an MOCVD method.

22. The method of manufacturing a group-III nitride compound semiconductor light-emitting device according to claim 1,
wherein the underlying layer is formed on the intermediate layer by a reactive sputtering method.

23. The method of manufacturing a group-III nitride compound semiconductor light-emitting device according to claim 1,
wherein, when the underlying layer is formed, the temperature of the substrate is not lower than 900° C.

24. A group-III nitride compound semiconductor light-emitting device comprising:
a substrate that is pre-processed by plasma processing;
an intermediate layer that is made of at least a group-III nitride compound and is formed on the substrate by a sputtering method;
an n-type semiconductor layer including an underlying layer;
a light-emitting layer; and
a p-type semiconductor layer,
wherein the n-type semiconductor layer, the light-emitting layer, and the p-type semiconductor layer are sequentially formed on the intermediate layer.

25. The group-III nitride compound semiconductor light-emitting device according to claim 24,
wherein the intermediate layer is formed of a single crystal.

26. The group-III nitride compound semiconductor light-emitting device according to claim 24,
wherein the intermediate layer is formed of a columnar crystal.

27. The group-III nitride compound semiconductor light-emitting device according to claim 26,
wherein, in the intermediate layer, the average of the widths of grains of the columnar crystals is in the range of 1 to 100 nm.

28. The group-III nitride compound semiconductor light-emitting device according to claim 26,
wherein, in the intermediate layer, the average of the widths of grains of the columnar crystals is in the range of 1 to 70 nm.

29. The group-III nitride compound semiconductor light-emitting device according to claim 24,
wherein the intermediate layer is formed so as to cover 90% or more of the front surface of the substrate.

30. The group-III nitride compound semiconductor light-emitting device according to claim 24,
wherein the thickness of the intermediate layer is in the range of 10 to 500 nm.

31. The group-III nitride compound semiconductor light-emitting device according to claim 24,
wherein the thickness of the intermediate layer is in the range of 20 to 100 nm.

32. The group-III nitride compound semiconductor light-emitting device according to claim 24,
wherein the intermediate layer has a composition including Al.

33. The group-III nitride compound semiconductor light-emitting device according to claim 32,
wherein the intermediate layer is formed of AlN.

34. The group-III nitride compound semiconductor light-emitting device according to claim 24,
wherein the underlying layer is formed of a GaN-based compound semiconductor.

35. The group-III nitride compound semiconductor light-emitting device according to claim 34,
wherein the underlying layer is formed of AlGaN.

36. A group-III nitride compound semiconductor light-emitting device manufactured by the manufacturing method according to claim 1.

37. A lamp comprising the group-III nitride compound semiconductor light-emitting device according to claim 24.
